(19) United States
(12) Patent Application Publication
(10) Pub. No.: US 2026/0293255 A1
(43) Pub. Date: Sep. 24, 2026

(54) BONDED SUBSTRATE, SEMICONDUCTOR DEVICE, AND METHOD OF PRODUCING BONDED SUBSTRATE

(71) Applicant: NGK INSULATORS, LTD., Nagoya-shi (JP)

(72) Inventors: Kei SATO, Tokai-shi (JP); Yoshitaka KURAOKA, Okazaki-shi (JP); Kentaro NONAKA, Gifu-shi (JP); Shohei OUE, Nagoya-shi (JP)

(21) Appl. No.: 19/571,062

(22) Filed: Mar. 18, 2026

(30) Foreign Application Priority Data
Mar. 19, 2025 (JP) 2025-045452

(51) Int. Cl. H10D 62/85; H10D 62/854; H10P 10/00

(52) U.S. Cl. CPC H10D 62/8503; H10D 62/854; H10P 10/128

(57) ABSTRACT

A bonded substrate includes: a Group-III element nitride layer; and a support substrate including a support layer. The Group-III element nitride layer has a carbon concentration of 5×10¹⁷ atoms/cm³ or more and 2×10¹⁹ atoms/cm³ or less.

### CROSS-REFERENCE TO RELATED APPLICATION

The present application claims priority from Japanese application JP2025-045452 filed on Mar. 19, 2025, the content of which is hereby incorporated by reference into this application.

### 1. FIELD OF THE INVENTION

The present disclosure relates to a bonded substrate, a semiconductor device, and a method of producing a bonded substrate.

### 2. DESCRIPTION OF THE RELATED ART

The development of a Group-III element nitride as, for example, a semiconductor material has been actively performed. As described in, for example, Japanese Patent No. 4458116, a bonded substrate in which a Group-III element nitride layer and a substrate having a thermal expansion coefficient close to that of the Group-III element nitride layer are joined to each other has been proposed as a substrate to be used in a semiconductor device using the Group-III element nitride.

### SUMMARY OF THE INVENTION

However, the above-mentioned bonded substrate may be insufficient in joining strength. For example, at the time of the formation of a device layer on the above-mentioned bonded substrate for obtaining a semiconductor device, peeling between the Group-III element nitride layer and the substrate may occur.

In view of the foregoing, a primary object of the present disclosure is to provide a bonded substrate excellent in joining strength.

1. According to at least one embodiment of the present disclosure, there is provided a bonded substrate, including: a Group-III element nitride layer; and a support substrate including a support layer, wherein the Group-III element nitride layer has a carbon concentration of 5×10¹⁷ atoms/cm³ or more and 2×10¹⁹ atoms/cm³ or less.

2. In the bonded substrate according to the above-mentioned item 1, the support layer may include one of gallium nitride, aluminum nitride, silicon carbide, diamond carbon, or diamond.

3. The bonded substrate according to the above-mentioned item 1 or 2 may have a disc shape and have a diameter of 4 inches or more.

4. In the bonded substrate according to any one of the above-mentioned items 1 to 3, the Group-III element nitride layer and the support layer in the support substrate may be directly joined to each other.

5. The bonded substrate according to any one of the above-mentioned items 1 to 4 may further include a joining layer arranged between the Group-III element nitride layer and the support layer in the support substrate. The joining layer may include one of silicon, tantalum oxide, alumina, aluminum nitride, silicon carbide, a sialon, or silicon oxide.

6. According to at least one embodiment of the present disclosure, there is provided a semiconductor device, including: the bonded substrate of any one of the above-mentioned items 1 to 5; and a device layer arranged on the bonded substrate.

7. According to at least one embodiment of the present disclosure, there is provided a method of producing a bonded substrate, including joining one of a Group-III element nitride layer or a Group-III element nitride substrate having a carbon concentration of 5×10¹⁷ atoms/cm³ or more and 2×10¹⁹ atoms/cm³ or less and a support substrate including a support layer to each other, wherein a surface of one of the Group-III element nitride layer or the Group-III element nitride substrate on a side to which the support substrate is joined has an arithmetic average roughness Ra of 1.0 nm or less.

8. In the method of producing a bonded substrate according to the above-mentioned item 7, the support layer may include one of gallium nitride, aluminum nitride, silicon carbide, diamond carbon, or diamond.

9. In the method of producing a bonded substrate according to the above-mentioned item 7 or 8, at a time of the joining, a joining surface on one of the Group-III element nitride layer side or the Group-III element nitride substrate side and a joining surface on the support substrate side may each be subjected to activation treatment.

### BRIEF DESCRIPTION OF THE DRAWINGS

FIG. 1A is a schematic sectional view for illustrating the schematic configuration of a bonded substrate according to at least one embodiment of the present disclosure.

FIG. 1B is a schematic sectional view for illustrating an example of details of a support substrate illustrated in FIG. 1A.

FIG. 1C is a schematic sectional view for illustrating the schematic configuration of a bonded substrate according to at least one embodiment of the present disclosure.

FIG. 2A is a view for illustrating an example of a production process for the bonded substrate according to at least one embodiment of the present disclosure.

FIG. 2B is a view subsequent to FIG. 2A.

FIG. 3A is a view for illustrating another example of the production process for the bonded substrate according to at least one embodiment of the present disclosure.

FIG. 3B is a view subsequent to FIG. 3A.

FIG. 4 is a schematic sectional view for illustrating the schematic configuration of a semiconductor device according to at least one embodiment of the present disclosure.

### DESCRIPTION OF THE EMBODIMENTS

Embodiments of the present disclosure are described below with reference to the drawings. The present disclosure is not limited to the embodiments. For clearer illustration, some widths, thicknesses, shapes, and the like of respective portions may be schematically illustrated in the drawings in comparison to the embodiments. However, the widths, the thicknesses, the shapes, and the like are each merely an example, and do not limit the interpretation of the present disclosure. In addition, in the drawings, the same or similar elements are denoted by the same reference symbols, and repetitive description thereof may be omitted.

### A. Bonded Substrate

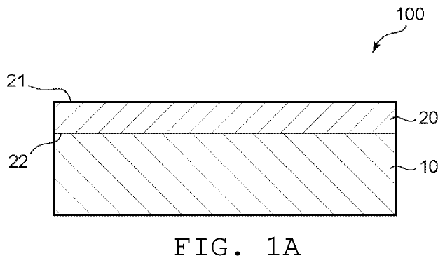

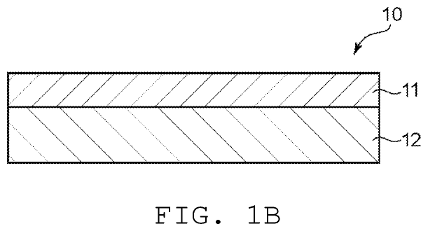

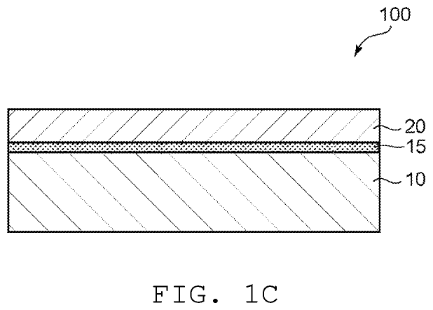

FIG. 1A is a schematic sectional view for illustrating the schematic configuration of a bonded substrate according to at least one embodiment of the present disclosure. A bonded substrate 100 includes a support substrate 10 and a Group-III element nitride layer 20 including a Group-III element nitride. The bonded substrate 100 includes: the Group-III element nitride layer 20 having a first main surface 21 and a second main surface 22 opposite to each other; and the support substrate 10 arranged on the second main surface 22 side of the Group-III element nitride layer 20. The bonded substrate 100 can be obtained by joining the support substrate 10 and the Group-III element nitride layer 20 to each other.

The support substrate 10 includes at least a support layer. The support layer in the support substrate 10 may include, for example, gallium nitride, aluminum nitride, silicon carbide, diamond, or diamond carbon. Such support layer can provide the bonded substrate 100 excellent in joining strength with the Group-III element nitride layer 20. In at least one embodiment of the present disclosure, the support layer may include a material (hereinafter sometimes referred to as “dissimilar material”) different from a material for forming the Group-III element nitride layer 20. The adoption of such configuration can provide, for example, the bonded substrate 100 satisfying a characteristic (e.g., a heat dissipation property) that cannot be achieved by the Group-III element nitride layer 20 alone. For example, the support layer preferably includes silicon carbide or aluminum nitride. Each of those materials has a high thermal conductivity, and hence can provide, for example, the bonded substrate 100 excellent in heat dissipation property.

The thickness of the support substrate 10 is preferably 100 μm or more and 1,000 μm or less, more preferably 200 μm or more and 1,000 μm or less. When the support substrate 10 is free of any layer other than the support layer (when the support substrate 10 includes only the support layer), the thickness of the support substrate 10 corresponds to the thickness of the support layer. When the support substrate 10 is free of any layer other than the support layer, the support substrate (support layer) 10 preferably includes gallium nitride, aluminum nitride, silicon carbide, or diamond. When the support substrate 10 is a laminate of a support layer 11 and a substrate 12 as illustrated in FIG. 1B, the thickness of the support layer 11 is preferably 20 μm or more and 300 μm or less, more preferably 20 μm or more and 100 μm or less. The substrate that may be incorporated into the support substrate 10 may include any appropriate material. The substrate 12 that may be incorporated into the support substrate 10 preferably includes, for example, silicon, mullite, sapphire, Hi-Ceram, alumina, a sialon, gallium nitride, silicon carbide, aluminum nitride, or diamond. When the support substrate 10 is a laminate of the support layer 11 and the substrate 12, the support substrate 10 is arranged in the bonded substrate 100 so that the support layer 11 may be positioned on the Group-III element nitride layer 20 side. Specifically, the support substrate 10 is subjected to the above-mentioned joining so that its support layer 11 may be positioned on the Group-III element nitride layer 20 side.

The support layer in the support substrate 10 may include a monocrystalline body, may include a polycrystalline body, may include an amorphous body, or may include a combination thereof. From the viewpoint of obtaining a more excellent joining strength, the support layer preferably includes a monocrystalline body. When the support layer includes a monocrystalline body, its crystal direction and the crystal direction of the Group-III element nitride layer 20 that may include a Group-III element nitride crystal may be set to any appropriate arrangements. In addition, the off direction (off-cut direction) of the support layer and the off direction of the Group-III element nitride layer 20 may be set to any appropriate arrangements. The off-cut of the support layer and the off-cut of the Group-III element nitride layer 20 may each be set to any appropriate value.

The Group-III element nitride layer 20 typically includes a Group-III element nitride crystal. The Group-III element nitride crystal typically has a hexagonal wurtzite crystal structure. In the Group-III element nitride crystal, typically, a <0001> direction is a c-axis direction, a <1-100> direction is an m-axis direction, and a <11-20> direction is an a-axis direction. In addition, a crystal plane perpendicular to the c-axis is a c-plane, a crystal plane perpendicular to the m-axis is an m-plane, and a crystal plane perpendicular to the a-axis is an a-plane. In at least one embodiment of the present disclosure, the thickness direction of the Group-III element nitride layer 20 is parallel or approximately parallel to the c-axis, and the first main surface 21 is a Group-III element polar surface on a (0001) plane side, and the second main surface 22 is a nitrogen polar surface on a (000-1) plane side. The first main surface 21 may be parallel to a (0001) plane, or may be tilted with respect to the (0001) plane. The angle of the tilt of the first main surface 21 with respect to the (0001) plane is, for example, 10° or less, and may be 5° or less, may be 2° or less, or may be 1° or less. The second main surface 22 may be parallel to a (000-1) plane, or may be tilted with respect to the (000-1) plane. The angle of the tilt of the second main surface 22 with respect to the (000-1) plane is, for example, 10° or less, and may be 5° or less, may be 2° or less, or may be 1° or less.

In at least one embodiment of the present disclosure, the thickness of the Group-III element nitride layer 20 is preferably 0.5 μm or more and 10 μm or less, more preferably 0.5 μm or more and 5 μm or less. In at least one embodiment of the present disclosure, the thickness of the Group-III element nitride layer 20 is preferably 100 μm or more and 1,000 μm or less, more preferably 200 μm or more and 1,000 μm or less.

For example, aluminum (Al), gallium (Ga), or indium (In) is used as a Group-III element for forming the above-mentioned Group-III element nitride. Those elements may be used alone or in combination thereof. Specific examples of the Group-III element nitride include aluminum nitride (AlₓN), gallium nitride (Ga_{y}N), indium nitride (In_{z}N), aluminum gallium nitride (AlₓGa_{y}N), gallium indium nitride (Ga_{y}In_{z}N), aluminum indium nitride (AlₓIn_{z}N), and aluminum gallium indium nitride ((AlₓGa_{y}In_{z}N). In each of the chemical formulae in parentheses, typically, x+y+z=1 is satisfied.

The Group-III element nitride layer 20 contains carbon. When the Group-III element nitride layer 20 contains carbon, the bonded substrate 100 may be excellent in joining strength. The carbon concentration of the Group-III element nitride layer 20 is preferably 5×10¹⁷ atoms/cm³ more, more preferably 1×10¹⁸ atoms/cm³ or more, still more preferably 2×10¹⁸ atoms/cm³ or more. Meanwhile, the carbon concentration of the Group-III element nitride layer 20 is preferably 2×10¹⁹ atoms/cm³ or less, more preferably 1×10¹⁹ atoms/cm³ or less. Such concentration enables the Group-III element nitride layer 20 to secure crystal quality. In the thickness direction of the Group-III element nitride layer 20, the carbon concentration may be uniform or may vary. For example, in the thickness direction of the Group-III element nitride layer 20, the carbon concentration may change periodically, may change continuously, or may change in a stepwise manner in the above-mentioned carbon concentration ranges. In addition, in the thickness direction of the Group-III element nitride layer 20, a region having a carbon concentration different from that of any other region may be partially formed.

The carbon concentration may be measured by, for example, secondary ion mass spectrometry (SIMS).

The Group-III element nitride layer 20 may be doped with an element except carbon. Specifically, the Group-III element nitride layer 20 may contain an element except carbon as a dopant. For example, a transition element, such as zinc (Zn), iron (Fe), manganese (Mn), vanadium (V), chromium (Cr), cobalt (Co), or nickel (Ni), is used as such dopant. Those dopants may be used alone or in combination thereof.

The Group-III element nitride layer 20 may be semi-insulating. In this case, the specific resistance of the Group-III element nitride layer 20 is, for example, 1×10⁵ Ω·cm or more and 1×10¹⁴ Ω·cm or less, preferably 1×10⁶ Ω·cm or more, more preferably 1×10⁷ Ω·cm or more.

The specific resistance may be measured by any appropriate method. Examples of the method of measuring the specific resistance include a capacitance method, a two-terminal method, and a double ring electrode method. In at least one embodiment of the present disclosure, a capacitance method is preferably used. The capacitance method enables the determination of the specific resistance without breakage of a measurement target. Specifically, the measurement target is inserted into a capacitor including a probe and a stage, a pulse voltage is applied thereto, and a change in charge amount of the measurement target with time is measured, followed by the calculation of the specific resistance from the measured value. At this time, the specific resistance can be determined without formation of any ohmic contact electrode because the probe is not brought into contact with the measurement target. The spatial resolution of the probe may be from about 1 mm to about 10 mm. A method of determining the specific resistance is described in, for example, “R. Stibal et al., “Contactless evaluation of semi-insulating GaAs wafer resistivity using the time-dependent charge measurement” Semiconductor Science and Technology 6 p 995 (1991)” that is a non patent literature.

The bonded substrate 100 may further include any appropriate layer. The kinds, functions, number, combination, arrangements, and the like of such layers may be appropriately set in accordance with purposes. For example, the bonded substrate 100 may include a device layer formed on the Group-III element nitride layer 20.

In addition, for example, as illustrated in FIG. 1C, the bonded substrate 100 may include a joining layer 15 arranged between the support layer in the support substrate 10 and the Group-III element nitride layer 20. Silicon, tantalum oxide, alumina, aluminum nitride, silicon carbide, a sialon, or silicon oxide (e.g., SiOₓ, 0<x≤2) is preferably used as a material for forming the joining layer 15 that may be incorporated into the bonded substrate 100. The sialon is a ceramic obtained by sintering a mixture of silicon nitride and alumina, and has by, composition represented for example, Si_{6-w}Al_{w}O_{w}N_{8-w}. Specifically, the sialon has such composition that alumina is mixed into silicon nitride, and “w” in the formula represents the mixing ratio of alumina. “w” preferably represents 0.5 or more and 4.0 or less.

The thickness of the joining layer is, for example, from 2 nm to 1 μm, preferably from 5 nm to 200 nm. The joining layer may be formed by any appropriate method. The layer may be formed by, for example, physical vapor deposition, such as sputtering, vacuum vapor deposition, or ion beam-assisted vapor deposition (IAD), chemical vapor deposition, or an atomic layer deposition (ALD) method. The joining layer may be formed at, for example, from room temperature (25° C.) to 300° C.

The bonded substrate 100 may be produced in any appropriate form. In at least one embodiment of the present disclosure, the substrate may be produced in the form of a so-called wafer (disc shape). An orientation flat or a notch may be formed in part of the bonded substrate 100 to indicate a crystal direction (e.g., the crystal direction of the wafer). The size of the bonded substrate 100 may be appropriately set in accordance with purposes. For example, the diameter of the wafer is from 50 mm to 200 mm, preferably 100 mm or more, or 4 inches or more. The bonded substrate 100 may have an excellent joining strength even when the substrate has such large size.

### B. Production Method

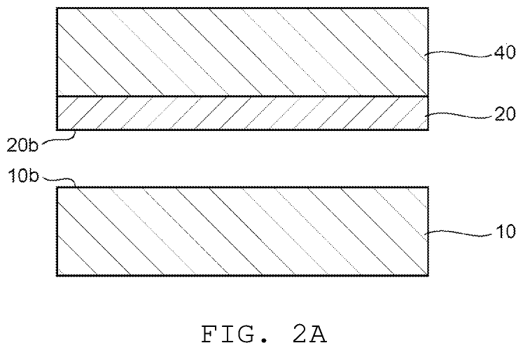

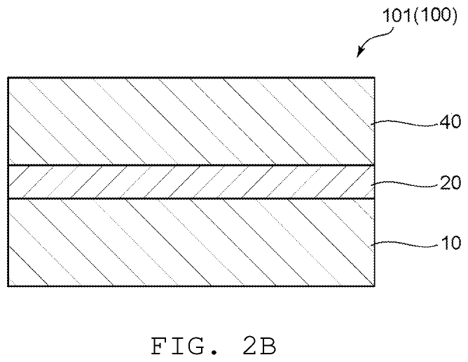

The above-mentioned bonded substrate may be obtained by, for example, joining the Group-III element nitride layer and the support substrate including the support layer to each other. FIG. 2A and FIG. 2B are each a view for illustrating an example of a production process for the bonded substrate according to at least one embodiment of the present disclosure. The support substrate 10 and the Group-III element nitride layer 20 are prepared as illustrated in FIG. 2A, and are directly joined to each other to provide a joined body 101 (the bonded substrate 100) of the support substrate 10 and the Group-III element nitride layer 20 as illustrated in FIG. 2B. In the illustrated example, the Group-III element nitride layer 20 is integrated with another substrate 40 at the time of its joining with the support substrate 10. Then, after the Group-III element nitride layer 20 and the support substrate 10 have been joined to each other, the other substrate 40 may be removed from the Group-III element nitride layer 20 (joined body 101).

The Group-III element nitride layer 20 integrated with the other substrate 40 is formed by, for example, a vapor phase growth method. Specific examples of the vapor phase growth method include a metal-organic chemical vapor deposition (MOCVD) method, a hydride vapor phase epitaxy (HVPE) method, a pulsed excitation deposition (PXD) method, a molecular-beam epitaxy (MBE) method, a vapor deposition method, and a sublimation method. Of those, a MOCVD method is preferably used.

When the Group-III element nitride layer 20 is formed by the above-mentioned MOCVD method, a metal-organic (MO) raw material gas may be used as a Group-III element source. For example, when a gallium nitride layer is formed by the MOCVD method, trimethylgallium (TMG) may be used as a Ga source. In addition, an ammonia gas may be used as a nitrogen source. In addition, for example, a hydrogen gas or a nitrogen gas may be used as a carrier gas. The temperature at which the Group-III element nitride layer 20 is formed by the MOCVD method may be adjusted within the range of, for example, from 500° C. to 1,200° C.

The Group-III element nitride layer 20 may be typically formed by using a base substrate (not shown). In at least one embodiment of the present disclosure, after the formation of the Group-III element nitride layer 20 on the base substrate, the other substrate 40 is integrated with the Group-III element nitride layer 20 by any appropriate method, and then the base substrate is removed from the Group-III element nitride layer 20. The Group-III element nitride layer 20 and the other substrate 40 may be typically integrated with each other by using an adhesive. A method of removing the base substrate from the Group-III element nitride layer 20 is, for example, machining, such as grinding or polishing, slicing with a wire saw, a laser, or the like, or a laser lift-off method including applying laser light. When the laser lift-off method is adopted, for example, the Group-III element nitride layer 20 is formed after the formation of a peeling layer, which can absorb the laser light, on the base substrate.

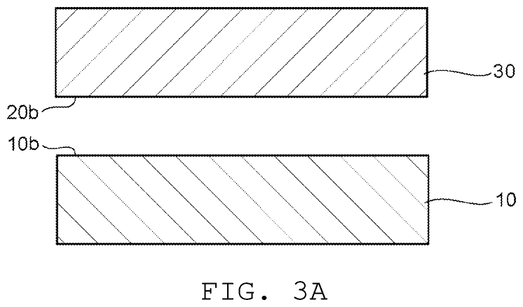

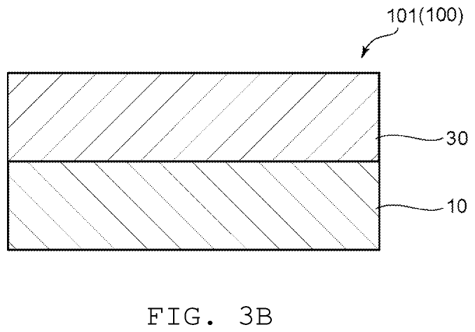

In addition, for example, the above-mentioned bonded substrate may be obtained as follows: a Group-III element nitride substrate and the support substrate including the support layer are joined to each other, and the Group-III element nitride substrate is thinned as required to provide the bonded substrate including the Group-III element nitride layer and the support substrate. FIG. 3A and FIG. 3B are each a view for illustrating another example of the production process for the bonded substrate according to at least one embodiment of the present disclosure. The support substrate 10 and a Group-III element nitride substrate 30 are prepared as illustrated in FIG. 3A, and are directly joined to each other to provide the joined body 101 (bonded substrate 100) of the support substrate 10 and the Group-III element nitride substrate 30 as illustrated in FIG. 3B. The bonded substrate 100 may be obtained by subjecting the joined body 101 to any appropriate processing after the joining. Specifically, after the joining, the Group-III element nitride substrate 30 may be thinned by grinding, polishing, or the like to provide the Group-III element nitride layer 20, or the Group-III element nitride substrate 30 may be used as it is as the Group-III element nitride layer 20.

The thickness of the Group-III element nitride substrate 30 is, for example, 100 μm or more and 1,000 μm or less. A substrate produced by any appropriate method may be used as the Group-III element nitride substrate 30. For example, the Group-III element nitride substrate 30 may be formed by a hydride vapor phase epitaxy (HVPE) method.

When a joining layer, which is not shown, is arranged, the bonded substrate may be obtained by joining the support substrate having formed thereon the joining layer and the Group-III element nitride layer or the Group-III element nitride substrate to each other, the bonded substrate may be obtained by joining the support substrate and the Group-III element nitride layer or the Group-III element nitride substrate having formed thereon the joining layer to each other, or the bonded substrate may be obtained by joining a first joining layer formed on the support substrate and a second joining layer formed on the Group-III element nitride layer or the Group-III element nitride substrate to each other.

### <Joining>

At the time of the above-mentioned direct joining, a joining surface 10b of the support substrate 10 and a joining surface 20b of the Group-III element nitride layer 20 or the Group-III element nitride substrate 30 are each preferably activated by any appropriate activation treatment.

The above-mentioned activation treatment is typically performed by applying a neutralized beam to each of the joining surfaces. The activation treatment is preferably performed by: generating the neutralized beam with such an apparatus as described in Japanese Patent Application Laid-open No. 2014-086400; and applying the beam thereto. Specifically, a saddle-field fast atomic beam (FAB) source is used as a beam source, and an inert gas, such as argon or xenon, is introduced into its chamber, followed by the application of a high voltage from its DC power supply to its electrodes. Thus, a saddle-field electric field is generated between the electrode (positive electrode) and casing (negative electrode) of the source to move an electron, and hence the beams of atoms and ions are generated by the inert gas. The ion beams out of the beams that have reached a grid are neutralized by the grid, and hence the beams of neutral atoms are emitted from the fast atomic beam source. A voltage at the time of the activation treatment by the beam application is preferably set to from 0.5 kV to 2.0 kV, and a current at the time of the activation treatment by the beam application is preferably set to from 50 mA to 200 mA.

After the activation treatment, the joining surface 10b of the support substrate 10 and the joining surface 20b of the Group-III element nitride layer 20 or the Group-III element nitride substrate 30 can be directly joined to each other by being brought into contact with each other and pressurized. The contact and pressurization of the joining surfaces are preferably performed in a vacuum atmosphere. A temperature at this time is typically normal temperature. Specifically, the temperature is preferably 20° C. or more and 40° C. or less, more preferably 25° C. or more and 30° C. or less. A pressure to be applied is preferably from 100 N to 20,000 N.

When a joining layer, which is not shown, is arranged, the joining surface of the joining layer and the joining surface of the support substrate, or of the Group-III element nitride layer or the Group-III element nitride substrate are each preferably activated by any appropriate activation treatment. Alternatively, the joining surfaces of a first joining layer and a second joining layer are each preferably activated by any appropriate activation treatment. Then, after the activation treatment, the joining surfaces can be directly joined to each other by being brought into contact with each other and pressurized. Conditions for the activation treatment and the joining may be the same as those described above.

At the time of the joining, the joining surfaces are preferably turned into flat surfaces. Specifically, the joining surface on the support substrate 10 side and the joining surface on the Group-III element nitride layer 20 side or the Group-III element nitride substrate 30 side are each preferably turned into a flat surface. When the joining surfaces are flat surfaces, an excellent joining strength can be achieved. The arithmetic average roughness Ra of each of the joining surfaces is, for example, 2.0 nm or less, preferably 1.0 nm or less, more preferably 0.7 nm or less, still more preferably 0.5 nm or less, particularly preferably 0.3 nm or less. A method of flattening the surface of each of the support substrate 10, the Group-III element nitride layer 20, and the Group-III element nitride substrate 30 is, for example, mirror polishing based on chemical-mechanical polishing (CMP), lap polishing, or the like. When a joining layer is arranged, the surface of each of the support substrate 10, the Group-III element nitride layer 20, and the Group-III element nitride substrate 30 on which the joining layer is formed is a flat surface, and hence the joining surface of the joining layer formed thereon may also be a flat surface.

When the carbon concentration of the surface 20b of the Group-III element nitride layer 20 or the Group-III element nitride substrate 30 on the side to which the support substrate 10 is joined is 2×10¹⁹ atoms/cm³ or less, the above-mentioned arithmetic average roughness Ra can be satisfactorily achieved. Specifically, when the carbon concentration of the Group-III element nitride layer 20 or the Group-III element nitride substrate 30 is 2×10¹⁹ atoms/cm³ or less, the crystal quality of the Group-III element nitride layer 20 or the Group-III element nitride substrate 30 is secured, and hence the above-mentioned arithmetic average roughness Ra can be satisfactorily achieved by flattening processing.

At the time of the joining, for example, to remove the residue of a polishing agent, the joining surfaces are preferably washed. A method for the cleaning is, for example, wet cleaning, dry cleaning, or scrub cleaning. Of those, scrub cleaning is preferred because the surfaces can be simply and efficiently cleaned. The scrub cleaning is specifically, for example, a method including: cleaning the surfaces with a cleaning agent (e.g., SUNWASH Series manufactured by Lion Corporation); and then cleaning the surfaces with a solvent (e.g., a mixed solution of acetone and isopropyl alcohol (IPA)) in a scrub cleaning machine.

### C. Application

The above-mentioned bonded substrate is typically applicable to any appropriate semiconductor device. Specifically, any appropriate device layer may be formed on the bonded substrate. The device layer is typically formed by epitaxially growing a crystal. As described above, the bonded substrate may be excellent in joining strength. Accordingly, even when the bonded substrate is exposed to a high temperature (of, for example, 1,000° C. or more) at the time of the formation of the device layer, the occurrence of an inconvenience such as delamination in the bonded substrate is suppressed, and hence a semiconductor device can be produced in high yield.

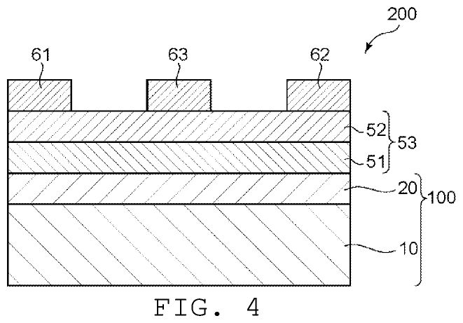

FIG. 4 is a schematic sectional view for illustrating the schematic configuration of a semiconductor device according to at least one embodiment of the present disclosure by using a high electron mobility transistor (HEMT) as an example. A HEMT device 200 includes the bonded substrate 100, a device layer 53 including a channel layer 51 and a barrier layer 52 in the stated order, and a source electrode 61, a drain electrode 62, and a gate electrode 63 arranged on the device layer 53. Those electrodes may each be a metal electrode having a thickness of from about a little over ten nanometers to about a hundred and several tens of nanometers.

The device layer 53 typically includes a Group-III element nitride, and may be formed by epitaxially growing a crystal above the Group-III element nitride layer 20. The thickness of the channel layer 51 is, for example, from 50 nm to 5 μm. The thickness of the barrier layer 52 is, for example, from 2 nm to 40 nm. In at least one embodiment of the present disclosure, the channel layer 51 preferably includes gallium nitride. In addition, the barrier layer 52 preferably includes at least one selected from aluminum gallium nitride, aluminum indium nitride, and aluminum indium gallium nitride.

A vapor phase growth method is typically used as a method of forming (growing) the device layer 53. Specific examples of the vapor phase growth method include a metal-organic chemical vapor deposition (MOCVD) method, a hydride vapor phase epitaxy (HVPE) method, a pulsed excitation deposition (PXD) method, a molecular-beam epitaxy (MBE) method, a vapor deposition method, and a sublimation method. Of those, a MOCVD method is preferably used. The formation temperature (growth temperature) of the device layer is, for example, 800° C. or more and 1, 200° C. or less, preferably 1,000° C. or more.

### EXAMPLES

The present disclosure is specifically described below by way of Examples, but the present disclosure is not limited to these Examples. A carbon concentration and an arithmetic average roughness Ra are values measured by the following measurement methods.

### <Carbon Concentration>

The carbon concentration of a gallium nitride layer was measured by secondary ion mass spectrometry (SIMS). Measurement conditions are as described below.

### (Measurement Conditions)

Kind of secondary ion mass spectrometer:
   a magnetic sector type
Kind of primary ion: Cs⁺

### <Arithmetic Average Roughness Ra>

The arithmetic average roughness Ra of a substrate was measured with an atomic force microscope (“AFM 5400L” manufactured by Hitachi High-Tech Corporation) in a field of view measuring 10 μm by 10 μm.

### Example 1

### (Production of Gallium Nitride Substrate)

A c-plane sapphire substrate having a diameter of 4 inches was prepared. A gallium nitride film having a thickness of 2 μm was formed on the sapphire substrate by a MOCVD method to produce a seed crystal substrate.

A gallium nitride crystal was grown on the seed crystal substrate with a crystal-producing apparatus including: a pressure-resistant vessel to which a pressurized nitrogen gas was able to be supplied; a rotary table capable of rotating in the pressure-resistant vessel; an outer vessel mounted on the rotary table; and a crystal growth furnace for placing the outer vessel under a desired temperature environment.

The resultant seed crystal substrate was placed in an alumina crucible in a glove box under a nitrogen atmosphere. Next, 40 g of metal gallium and 80 g of metal sodium were each melted in the glove box and loaded into the crucible so that the seed crystal substrate was immersed in a flux melt, followed by the covering of the crucible with an alumina plate. In this state, the crucible was loaded into a stainless steel-made inner vessel, and the inner vessel was further loaded into a stainless steel-made outer vessel capable of holding the inner vessel, followed by the closing of the outer vessel with a lid provided with a nitrogen-introducing pipe. In this state, the outer vessel was mounted on the rotary table arranged in the crystal-producing apparatus, and the pressure-resistant vessel of the crystal-producing apparatus was covered with a lid and hermetically sealed.

Subsequently, while a heating unit was operated to heat the crystal growth furnace in the crystal-producing apparatus so that its temperature became 875° C. uniformly, a nitrogen gas was introduced into the pressure-resistant vessel from a nitrogen gas cylinder until a pressure therein became 4 MPa, and the outer vessel was horizontally rotated. This state was held for 70 hours to grow a gallium nitride crystal.

After that, the temperature was naturally cooled to room temperature, and the pressure was reduced to atmospheric pressure. After that, the lid of the pressure-resistant vessel was opened, and the crucible was removed from its inside. Solidified metal sodium in the crucible was removed, and a seed crystal substrate in which a gallium nitride crystal had been grown was recovered.

Next, at room temperature, UV laser light was applied from the sapphire substrate side of the seed crystal substrate in which the gallium nitride crystal had been grown to decompose the gallium nitride film of the seed crystal substrate. Thus, the grown gallium nitride crystal was separated from the sapphire substrate. The separated gallium nitride crystal was fixed to a ceramic-made surface plate for processing, and both of its main surfaces were polished with a grinder and a lapping apparatus to be flattened. Thus, a gallium nitride substrate (base substrate) having a diameter of 4 inches and a thickness of 350 μm was produced.

### (Formation of Gallium Nitride Layer)

A 1,000-nanometer thick peeling layer that was decomposed by being irradiated with laser light having a wavelength of 532 nm was formed on the main surface of the resultant gallium nitride substrate on a gallium polar surface side by a MOCVD method. After the formation of the peeling layer, a gallium nitride layer doped with carbon (C) was continuously formed thereon by the MOCVD method. Specifically, a hydrogen gas was flowed in a MOCVD furnace, and a gallium nitride layer having a thickness of 3 μm and a carbon concentration of 2×10¹⁸ atoms/cm³ was formed by using an ammonia gas and trimethylgallium (TMG) under the conditions of a furnace internal pressure of 0.3 atm and a substrate temperature of 1,050° C. Thus, an epitaxial substrate was obtained.

A sapphire substrate was bonded to the gallium nitride layer side of the resultant epitaxial substrate with an adhesive, and then the gallium nitride substrate was peeled from the epitaxial substrate. Specifically, laser light was applied from the gallium nitride substrate side to the epitaxial substrate, and after the application of the laser light, the epitaxial substrate was immersed in a water bath at 50° C. so that the gallium nitride substrate was peeled.

The peeled surface of the gallium nitride layer from which the gallium nitride substrate had been peeled was polished by CMP until the thickness of the gallium nitride layer became 2 μm. The arithmetic average roughness Ra of the surface (joining surface) of the gallium nitride layer was 0.35 nm.

(Joining with Support Substrate)

A silicon carbide substrate having a diameter of 4 inches and a thickness of 500 μm was prepared as a support substrate. The arithmetic average roughness Ra of the surface (joining surface) of the silicon carbide substrate was 0.24 nm.

Next, the gallium nitride layer integrated with the sapphire substrate and the support substrate were directly joined to each other. Specifically, after the joining surface of the gallium nitride layer and the joining surface of the support substrate had been cleaned, both the substrates were loaded into a vacuum chamber, and the chamber was evacuated to a pressure of the order of 10⁻⁶ Pa, followed by the irradiation of the joining surfaces of both the substrates with fast atomic beams (acceleration voltage: 1 kV, Ar flow rate: 27 sccm) for 120 seconds. After the irradiation, the beam-irradiated surfaces of both the substrates were superimposed on each other, and were pressurized at 10,000 N for 2 minutes so that both the substrates were joined to each other.

After that, the sapphire substrate was removed from the resultant joined body through the decomposition of the adhesive by heating, and then the surface of the gallium nitride layer was cleaned. Thus, a bonded substrate was obtained.

### Example 2

A bonded substrate was obtained in the same manner as in Example 1 except that in the formation of a gallium nitride layer by the MOCVD method, the formation conditions were changed, and a gallium nitride layer having a carbon concentration of 7×10¹⁷ atoms/cm³ was obtained. The arithmetic average roughness Ra of the joining surface of the gallium nitride layer was 0.40 nm.

### Example 3

A bonded substrate was obtained in the same manner as in Example 1 except that: in the production of a gallium nitride substrate, the diameter of the sapphire substrate was changed to 6 inches; in the formation of a gallium nitride layer by the MOCVD method, the formation conditions were changed, and a gallium nitride layer including a first gallium nitride layer, which had a thickness of 2 μm and a carbon concentration of 5×10¹⁸ atoms/cm³, and a second gallium nitride layer, which had a thickness of 1 μm and a carbon concentration of 8×10¹⁸ atoms/cm³, in the stated order from its gallium nitride substrate side was obtained; and a silicon carbide substrate having a diameter of 6 inches and a thickness of 500 μm was used as a support substrate. The gallium nitride layer after its polishing included the first gallium nitride layer having a thickness of 1 μm and the second gallium nitride layer having a thickness of 1 μm, and its joining surface had an arithmetic average roughness Ra of 0.35 nm.

### Example 4

A bonded substrate was obtained in the same manner as in Example 1 except that: a polycrystalline aluminum nitride substrate having a diameter of 4 inches and a thickness of 500 μm (whose joining surface had an arithmetic average roughness Ra of 1.20 nm) was used as a support substrate; and in the formation of a gallium nitride layer by the MOCVD method, a gallium nitride layer having a thickness of 4 μm was obtained. Herein, the thickness of the gallium nitride layer after its polishing was set to 3 μm.

### Comparative Example 1

A bonded substrate was obtained in the same manner as in Example 1 except that in the formation of a gallium nitride layer by the MOCVD method, the formation conditions were changed, and a gallium nitride layer having a carbon concentration of 3×10¹⁷ atoms/cm³ was obtained. The arithmetic average roughness Ra of the joining surface of the gallium nitride layer was 0.50 nm.

### Comparative Example 2

A bonded substrate was obtained in the same manner as in Example 1 except that in the formation of a gallium nitride layer by the MOCVD method, the formation conditions were changed, and a gallium nitride layer having a carbon concentration of 2.5×10¹⁹ atoms/cm³ was obtained. The arithmetic average roughness Ra of the joining surface of the gallium nitride layer was 2.21 nm.

### Evaluation

The bonded substrates obtained in Examples and Comparative Examples were evaluated for their joining strengths by a crack opening method.

Specifically, the gallium nitride substrate and support substrate of each of the bonded substrates were mechanically peeled from each other with a blade having a thickness (t_{b}) of 100 μm. The blade was inserted into an end surface of the bonded substrate, and a distance (L) from the tip of the blade to the site at which the peeling had advanced to the largest extent was measured, followed by the calculation of a surface energy (γ) through use of the following equation. The calculated value was defined as a joining strength. The evaluation results are summarized in Table 1.

$$γ = \frac{3 {t}_{b}^{2} {E}_{1} {t}_{w 1}^{3} {E}_{2} {t}_{w 2}^{3}}{16 {L}^{4} ( {E}_{1} {t}_{w 1}^{3} + {E}_{2} {t}_{w 2}^{3} )}$$

γ: the surface energy (J/m²)
L: the distance (μm) from the tip of the blade to the site at which the peeling had advanced to the largest extent
t_{w1}: the thickness (μm) of the gallium nitride substrate
t_{w2}: the thickness (μm) of the support substrate
E₁: the Young's modulus (MPa) of the gallium nitride substrate
E₂: the Young's modulus (MPa) of the support substrate to the thickness (μm) of the blade

TABLE 1

| | | | Example | Example | Example | Example |
|---|---|---|---|---|---|---|
| | | | 1 | 2 | 3 | 4 |
| Diameter | | (inches) | 4 | 4 | 6 | 4 |
| GaN | Carbon | [atoms/cm³] | 2 × 10¹⁸ | 7 × 10¹⁷ | 5 × 10¹⁸ | 2 × 10¹⁸ |
| substrate | concentration | | | | | |
| | Ra | [nm] | 0.35 | 0.40 | 0.35 | 0.35 |
| Support | Material | | SiC | SiC | SiC | AlN |
| substrate | Ra | [nm] | 0.24 | 0.24 | 0.24 | 1.20 |

| | | | | | |
|---|---|---|---|---|---|
| Joining strength | [J/m²] | >1.8 | >1.8 | >1.8 | >1.8 |

| | | | Comparative | Comparative |
|---|---|---|---|---|
| | | | Example 1 | Example 2 |
| Diameter | | (inches) | 4 | 4 |
| GaN | Carbon | [atoms/cm³] | 3 × 10¹⁷ | 2.5 × 10¹⁹ |
| substrate | concentration | | | |
| | Ra | [nm] | 0.50 | 2.21 |

| | | | |
|---|---|---|---|
| Support | Material | SiC | SiC |

| | | | | |
|---|---|---|---|---|
| substrate | Ra | [nm] | 0.24 | 0.24 |

| | | | |
|---|---|---|---|
| Joining strength | [J/m²] | 1.5 | 1.1 |

The bonded substrate according to at least one embodiment of the present disclosure is applicable to, for example, a semiconductor device.

According to at least one embodiment of the present disclosure, the bonded substrate excellent in joining strength can be provided.

What is claimed is:

1. A bonded substrate, comprising:
a Group-III element nitride layer; and
a support substrate including a support layer,
wherein the Group-III element nitride layer has a carbon concentration of 5×10¹⁷ atoms/cm³ or more and 2×10¹⁹ atoms/cm³ or less.

2. The bonded substrate according to claim 1, wherein the support layer includes one of gallium nitride, aluminum nitride, silicon carbide, diamond carbon, or diamond.

3. The bonded substrate according to claim 1, wherein the bonded substrate has a disc shape and has a diameter of 4 inches or more.

4. The bonded substrate according to claim 1, wherein the Group-III element nitride layer and the support layer in the support substrate are directly joined to each other.

5. The bonded substrate according to claim 1, further comprising a joining layer arranged between the Group-III element nitride layer and the support layer in the support substrate, wherein the joining layer includes one of silicon, tantalum oxide, alumina, aluminum nitride, silicon carbide, a sialon, or silicon oxide.

6. A semiconductor device, comprising:
the bonded substrate of claim 1; and
a device layer arranged on the bonded substrate.

7. A method of producing a bonded substrate, comprising joining one of a Group-III element nitride layer or a Group-III element nitride substrate having a carbon concentration of 5×10¹⁷ atoms/cm³ or more and 2×10¹⁹ atoms/cm³ or less and a support substrate including a support layer to each other, wherein a surface of one of the Group-III element nitride layer or the Group-III element nitride substrate on a side to which the support substrate is joined has an arithmetic average roughness Ra of 1.0 nm or less.

8. The method of producing a bonded substrate according to claim 7, wherein the support layer includes one of gallium nitride, aluminum nitride, silicon carbide, diamond carbon, or diamond.

9. The method of producing a bonded substrate according to claim 7, wherein at a time of the joining, a joining surface on one of the Group-III element nitride layer side or the Group-III element nitride substrate side and a joining surface on the support substrate side are each subjected to activation treatment.

10. A bonded substrate, comprising:
a Group-III element nitride layer; and
a support substrate including a support layer,
wherein the Group-III element nitride layer has a carbon concentration of 5×10¹⁷ atoms/cm³ or more and 2×10¹⁹ atoms/cm³ or less,
wherein the support layer includes one of gallium nitride, aluminum nitride, silicon carbide, diamond carbon, or diamond,
wherein the bonded substrate has a disc shape and has a diameter of 4 inches or more, and
wherein the Group-III element nitride layer and the support layer in the support substrate are directly joined to each other.
